(19) United States
(12) Patent Application Publication
(10) Pub. No.: US 2015/0068444 A1
(43) Pub. Date: Mar. 12, 2015

(54) HOLDER, CRYSTAL GROWING METHOD, AND CRYSTAL GROWING APPARATUS

(71) Applicant: KYOCERA CORPORATION, Kyoto-shi, Kyoto (JP)

(72) Inventors: Katsuaki Masaki, Kyoto-shi (JP); Yutaka Kuba, Kyoto-shi (JP); Chiaki Domoto, Kyoto-shi (JP)

(73) Assignee: KYOCERA CORPORATION, Kyoto-shi, Kyoto (JP)

(21) Appl. No.: 14/397,179

(22) PCT Filed: Apr. 26, 2013
(86) PCT No.: PCT/JP2013/062393

§ 371 Date: Oct. 24, 2014

(30) Foreign Application Priority Data
Apr. 26, 2012 (JP) 2012-100526
Jul. 30, 2012 (JP) 2012-168246

(51) Int. Cl. C30B 15/32; C30B 29/36

(52) U.S. Cl. CPC C30B 15/32; C30B 29/36
USPC 117/13; 117/215

(57) ABSTRACT

A holder according to one embodiment is a holder which is used in a solution growth method of growing a crystal on a lower surface of a seed crystal by contacting the lower surface of the seed crystal with a solution of silicon including carbon in a crucible having an opening on an upper end thereof. The holder includes: a holding member which holds the seed crystal on a lower surface; the seed crystal which is held on the lower surface of the holding member, has an upper surface larger than the lower surface, and is made of silicon carbide; and a suppressing member which is fixed to a side surface of the holding member, continues from the side surface to outside further outward than an outer circumference of the seed crystal in plan view, and suppresses upward movement of vapor from the solution.

### TECHNICAL FIELD

The present invention relates to a holder in which a seed crystal is bonded to a holding member having a suppressing member, a crystal growing method of growing a crystal by using the holder, and a crystal growing apparatus including the holding member having the suppressing member.

### BACKGROUND ART

As a crystal which attracts attention nowadays, there is a silicon carbide (SiC) which is a compound of carbon and silicon. The silicon carbide is advantageous, for example, in voltage endurance characteristics. Examples of a method of growing a crystal of the silicon carbide include a solution growth method or a sublimation method. The method of growing the crystal of the silicon carbide by the solution growth method is disclosed in Japanese Unexamined Patent Application Publication No. 2000-264790, for example.

### SUMMARY OF INVENTION

In studying and developing a growth of a crystal made of the silicon carbide, when the crystal is grown on a lower surface of a seed crystal, it is difficult to suppress a growth of miscellaneous crystals in the vicinity of the seed crystal. The invention is made in view of such situation, and the object of the invention is to provide a holder which can suppress the growth of miscellaneous crystals in the vicinity of the seed crystal, a crystal growing method using the holder and a crystal growing apparatus using the holder.

A holder according to the invention is a holder which is used in a solution growth method of growing a crystal on a lower surface of a seed crystal by contacting the lower surface of the seed crystal with a solution of silicon including carbon in a crucible having an opening on an upper end thereof. The holder includes: a holding member which holds the seed crystal on a lower surface of the holding member; the seed crystal which is held on the lower surface of the holding member, has an upper surface larger than the lower surface of the holding member, and is made of silicon carbide; and a suppressing member which is fixed to a side surface of the holding member, continues from the side surface to outside further outward than an outer circumference of the seed crystal in plan view, and suppresses upward movement of vapor from the solution.

In addition, a crystal growing method according to the invention includes: a first preparation step of preparing a crucible for growing a crystal, which has an opening at an upper end thereof and in which a solution of silicon including carbon is stored; a second preparation step of preparing the above-described holder; and a growing step of growing the crystal of silicon carbide from the solution on a lower surface of the seed crystal, by placing the holder in the crucible through the opening, positioning the suppressing member in the crucible together with the seed crystal, contacting the lower surface of the seed crystal with the solution, and pulling up the holding member.

Furthermore, a crystal growing apparatus according to the invention includes: a crucible for growing a crystal, which has an opening at an upper end thereof and in which a solution of silicon having carbon is stored; a holding member which is capable of being taken into and out of the crucible through the opening and holds, on a lower surface of the holding member, a seed crystal having an upper surface larger than the lower surface of the holding member; and a suppressing member which is fixed to a side surface of the holding member, continues from the side surface to outside further outward than an outer circumference of the seed crystal in plan view, and suppresses upward movement of vapor from the solution.

According to the present invention, when the crystal of the silicon carbide is grown by the solution growth method, such effects are achieved that the growth of miscellaneous crystals in the vicinity of the seed crystal is suppressed and the crystal of silicon carbide is made large or long.

### BRIEF DESCRIPTION OF DRAWINGS

FIG. 1 is a cross-sectional view illustrating an example of a holder according to a first embodiment of the present invention, and corresponds to a cross section when cut along line A-A′ in FIG. 2.

FIG. 2 corresponds to a plan view of the holder in FIG. 1 in perspective plan view.

FIG. 3 is a cross-sectional view illustrating an effect when the holder in FIG. 1 is used in a solution growth method.

FIG. 4 is an enlarged cross-sectional view in which a part in FIG. 3 is enlarged.

FIG. 5 is a view illustrating a modification of the holder in FIG. 1, and corresponds to a cross section when cut along line A-A′ in FIG. 2.

FIG. 6 is a view illustrating modifications of the holder in FIG. 1, and each illustration corresponds to a cross section of the holder when cut along line A-A′ in FIG. 2.

FIG. 7 is a view illustrating a modification of the holder in FIG. 1, where (a) is a perspective view from above, and (b) corresponds to a cross section when cut along line B-B′ in FIG. 7(a).

FIG. 8 is a view illustrating a modification of the holder in FIG. 1, in which a part of the holder is enlarged.

FIG. 9 is a view illustrating a modification of the holder in FIG. 1, and corresponds to a cross section when cut along line A-A′ in FIG. 2.

FIG. 10 is cross-sectional view illustrating an example of a holder according to a second embodiment of the present invention, and corresponds to a cross section when cut along line B-B′ in FIG. 10.

FIG. 11 corresponds to a plan view of the holder in FIG. 10 in perspective plan view.

FIG. 12 is an enlarged cross-sectional view which illustrates an effect when the holder in FIG. 10 is used in a solution growth method and in which a part thereof is enlarged.

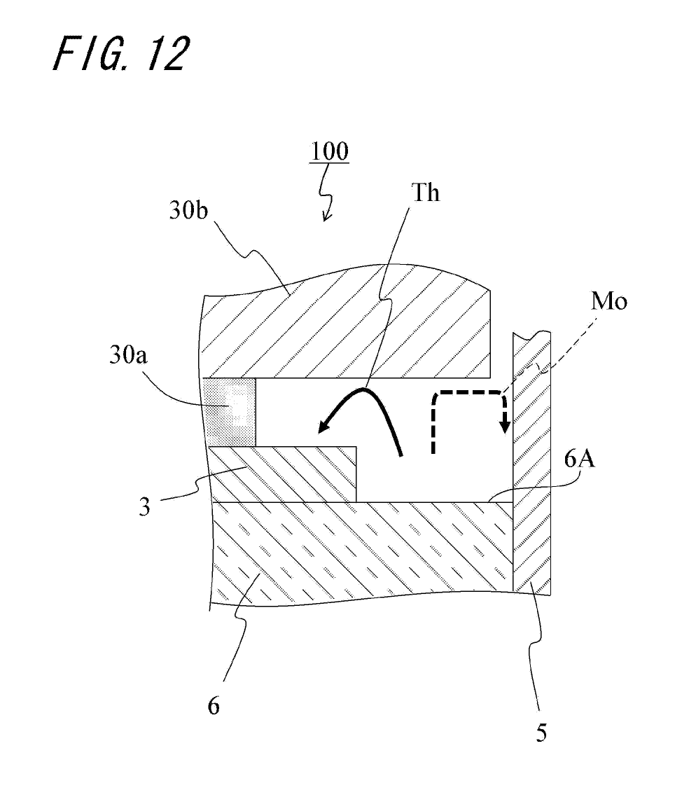

FIG. 13 is a view illustrating a modification of the holder in FIG. 10, where (a) corresponds to a cross section when cut along line B-B′ in FIG. 10, and (b) is an enlarged cross-sectional view which illustrates an effect when the holder is used in a solution method and in which a part thereof is enlarged.

FIG. 14 is a view illustrating a modification of the holder in FIG. 10, where (a) corresponds to a cross section when cut along line B-B′ in FIG. 10, and (b) is an enlarged cross-sectional view which illustrates an effect when the holder is used in a solution method and in which a part thereof is enlarged.

FIG. 15 is a view illustrating a modification of the holder in FIG. 10, and corresponds to a cross section when cut along line B-B′ in FIG. 10.

FIG. 16 is a view illustrating a modification of the holder in FIG. 10, and corresponds to a cross section when cut along line B-B′ in FIG. 10.

FIG. 17 is a view illustrating a modification of the holder in FIG. 16, and corresponds to a cross section when cut along line B-B′ in FIG. 10.

FIG. 18 is a cross-sectional view illustrating an example of a crystal growth apparatus including a holding member and a suppressing member according to the present invention.

### DESCRIPTION OF EMBODIMENTS

Embodiments of a holder, a crystal growing method, and a crystal growing apparatus according to the present invention will be described with reference to the drawings.

<First Embodiment of Holder>

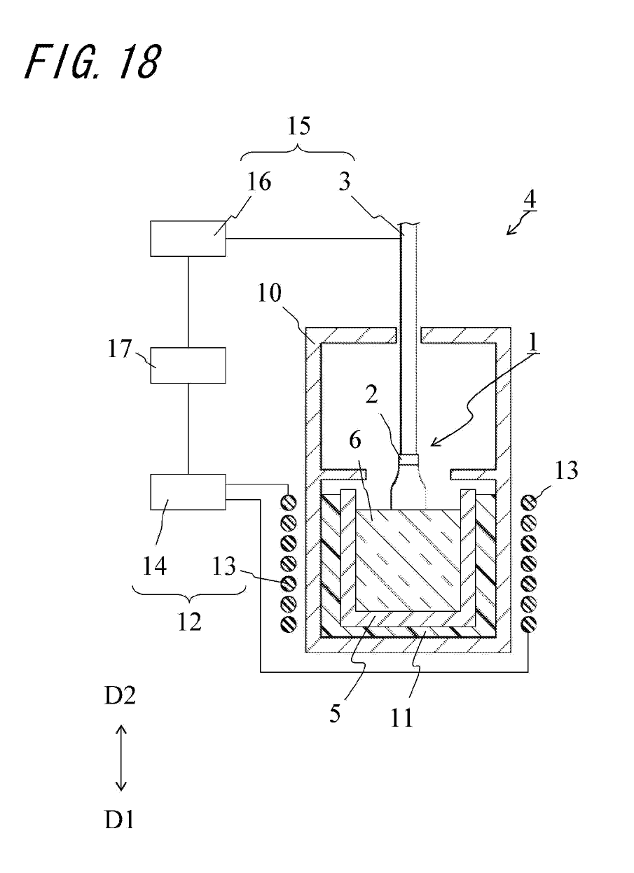

A holder 1 is mainly composed of a seed crystal 2, a holding member 3, and a suppressing member 8. As illustrated in FIG. 18, the holder 1 is attached to a crystal growing apparatus 4 and used.

The holder 1 according to the embodiment is used in a solution growth method in which a lower surface 2B of the seed crystal 2 is allowed to contact with a solution 6 of silicon including carbon in a crucible 5 having an opening 5a at an upper end thereof, and a crystal is grown on the lower surface 2B.

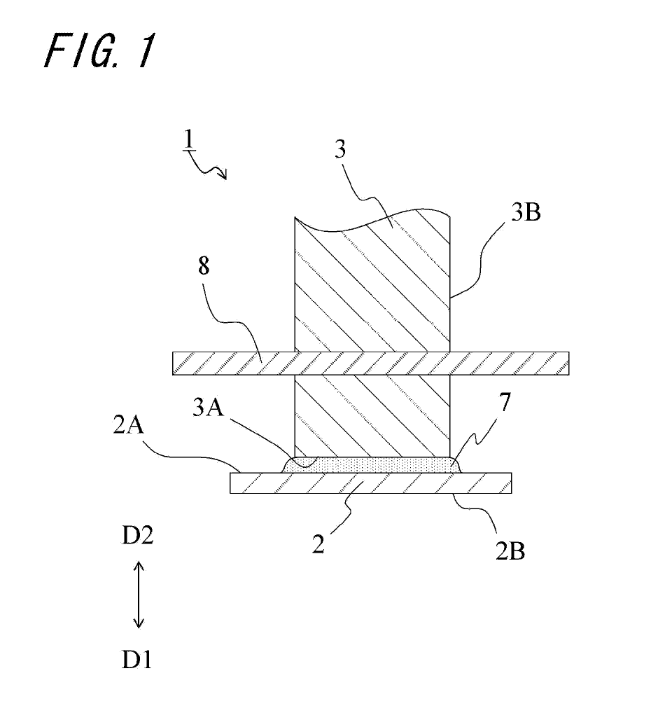

As illustrated in FIG. 1, the seed crystal 2 is fixed via an adhesive 7 on a lower surface 3A of the holding member 3. In other words, the holding member 3 is positioned above the seed crystal 2 with the adhesive 7 interposed therebetween. Here, FIG. 1 is a cross-sectional view in which a part of the holder 1 including the seed crystal 2, the adhesive 7, and the holding member 3 is enlarged. Note that, in FIG. 1, a downward direction is denoted by a D1 direction, and an upward direction is denoted by a D2 direction, and further in the description below, the directions are the same unless particularly mentioned.

The holding member 3 is not specifically limited as long as the lower surface 3A is included. The lower surface 3A has a polygonal shape such as a square shape, a circular shape, or the like in plan view. Accordingly, the holding member 3 has a three-dimensional shape, for example, in a rod shape such as a polygonal pillar shape or a cylindrical shape, or a rectangular parallelepiped shape.

A material for the holding member 3 can be appropriately selected, and the holding member 3 can be made of a material which has an oxide represented by a zirconium oxide and a magnesium oxide, or carbon, as a main component. As the holding member 3, it is possible to use, for example, a polycrystal of carbon or a fired body of carbon. In the embodiment, a case where the holding member 3 is made of carbon is described.

When the holding member 3 is made of the polycrystal of carbon or the fired body of carbon, it is possible to enhance porosity in the holding member 3. When the porosity of the holding member 3 increases, for example, it is possible to allow gas generated in the adhesive 7 to escape from the holding member 3, to suppress generation of bubbles or the like in the adhesive 7, and to maintain an adhesion strength with the adhesive 7.

The seed crystal 2 is made of the crystal of silicon carbide. For example, a single crystal or polycrystal of silicon carbide can be used as the crystal of the seed crystal 2. A thickness of the seed crystal 2 can be set to 0.1 mm or more and 10 mm or less, for example. An external shape of the seed crystal 2 in plan view is a polygonal shape or a circular shape, for example. A width dimension in a lateral direction of the seed crystal 2 can be set to 5 mm or more and 20 cm or less, for example.

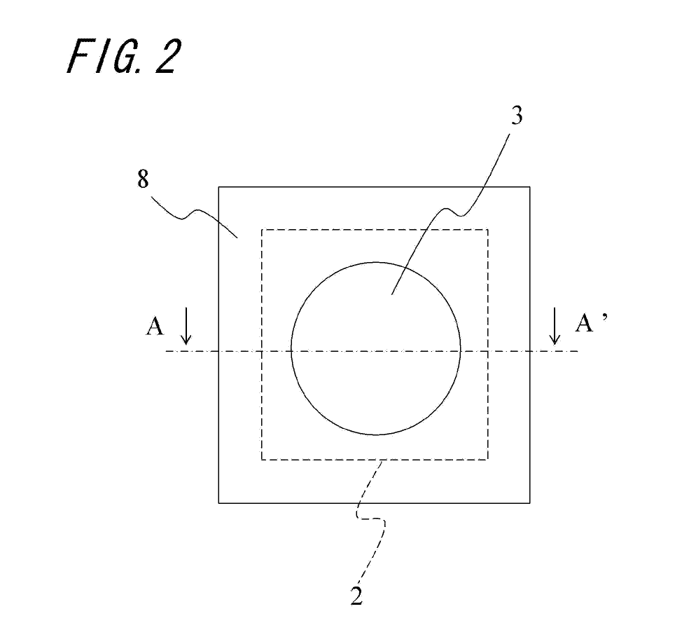

As illustrated in FIG. 2, the seed crystal 2 has an upper surface 2A which is larger than the lower surface 3A of the holding member 3. In other words, an area of the upper surface 2A of the seed crystal 2 is set to be greater than an area of the lower surface 3A of the holding member 3. Accordingly, a part of the upper surface 2A of the seed crystal 2 is fixed to the lower surface 3A of the holding member 3 via the adhesive 7. The area of the upper surface 2A of the seed crystal 2 can be set to 110% or more and 400% or less with respect to the lower surface 3A, for example.

The seed crystal 2 may be fixed to the lower surface 3A of the holding member 3 at any part of the upper surface 2A thereof. When the seed crystal 2 is fixed such that a region including a center of gravity of the seed crystal 2 is fixed to be overlapped with the lower surface 3A, the seed crystal 2 can be held with good balance. Accordingly, for example, it is possible to perform a crystal growth by maintaining the seed crystal 2 horizontally with respect to a liquid surface of the solution 6.

The adhesive 7 is disposed to be interposed between the upper surface 2A of the seed crystal 2 and the lower surface 3A of the holding member 3. In accordance with the material of the holding member 3, an appropriate material for the adhesive 7 can be set. As the adhesive 7, it is possible to use a ceramic adhesive including an aluminum oxide, a magnesium oxide, or a zirconium oxide, or a carbon adhesive which has carbon as the main component. In the embodiment, since the holding member 3 is made of carbon, it is possible to improve the adhesion strength by using the carbon adhesive, and to suppress generation of impurities even if the carbon adhesive melts. Note that, in the description below, the description of the adhesive 7 may be omitted.

The suppressing member 8 is fixed to a side surface 3B of the holding member 3, and to be disposed above the seed crystal 2. As described below, the suppressing member 8 may be disposed at a position where upward movement of vapor of the solution 6 can be suppressed when the seed crystal 2 is in contact with the solution 6. In the embodiment, the suppressing member 8 is disposed at a height (with respect to the upper surface 2A of the seed crystal 2) at which the suppressing member 8 is also placed in the crucible 5 when the seed crystal 2 is contact with the solution 6 in the crucible 5. Specifically, when the seed crystal 2 is in contact with the solution 6, the suppressing member 8 is disposed at a position which is lower than the opening 5a of the crucible 5. The suppressing member 8 is disposed so that the height thereof from the upper surface 2A of the seed crystal 2 is 3 mm or more and 15 cm or less, for example. In the embodiment, the suppressing member 8 is made of a board-shaped member.

In addition, the suppressing member 8 is fixed to the holding member 3 by an adhesive or the like. When the suppressing member 8 and the holding member 3 are made of carbon, it is possible to use, as the adhesive, the carbon adhesive which has carbon as the main component. In this case, since the suppressing member 8 and the holding member 3 are fixed to each other by carbon, it is possible to firmly fix both of these to each other. The suppressing member 8 may be formed to be integrated with the holding member 8. In this case, it is possible to further firmly fix the suppressing member 8.

Furthermore, as illustrated in FIG. 2, the suppressing member 8 is provided to continue from the side surface 3B to the outside further outward than the outer circumference of the seed crystal 2 in plan view. A size of the suppressing member 8 is not particularly limited as long as upward movement of vapor of the solution 6 is suppressed. In other words, the height and the size of the suppressing member 8 from the upper surface 2A of the seed crystal 2 are determined so that the upward movement of the vapor of the solution 6 is suppressed. The suppressing member 8 can be disposed so that the area of the upper surface 2A of the seed crystal 2 is 105% or more and 300% or less, for example.

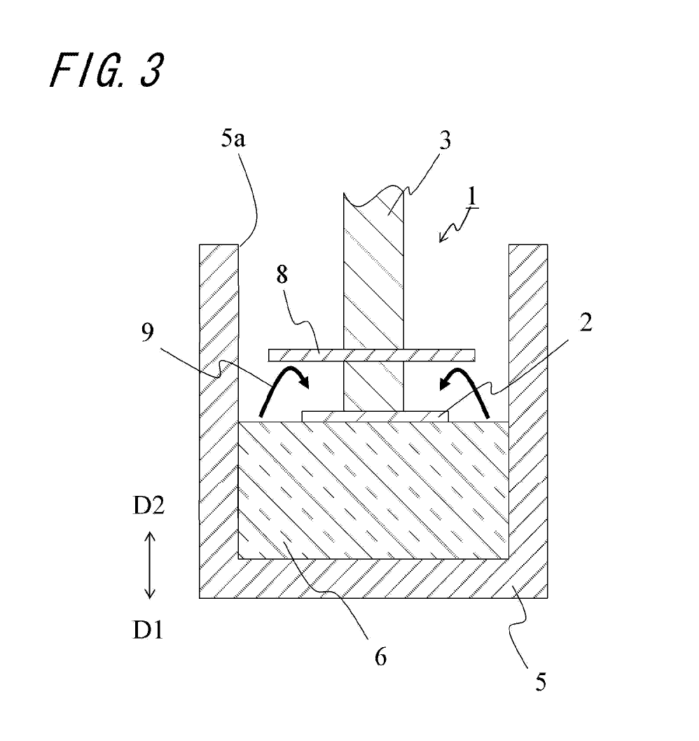

In the holder 1 of the embodiment, the suppressing member 8 which is positioned above the seed crystal 2 is fixed to the holding member 3. Accordingly, as illustrated in FIG. 3, the upward movement of vapor 9 of the solution 6 is suppressed by the suppressing member 8. Since the suppressing member 8 is provided to continue from the side surface 3C of the holding member 3, the vapor 9 flows to the upper surface 2A of the seed crystal 2 along the side surface 3C from the lower surface of the suppressing member 8. Accordingly, a temperature of the upper surface 2A of the seed crystal 2 or a temperature of the solution 6 which is positioned in the vicinity of the seed crystal 2 is maintained. As a result, it is possible to make it difficult for miscellaneous crystals caused by a difference between the temperatures of the seed crystal 2 and the atmosphere to be grown on the upper surface 2A of the seed crystal 2, and it is possible to make the crystal which is grown on the lower surface 2B of the seed crystal 2 large or long. Here, the miscellaneous crystals represent a crystal which is unintentionally grown approximately in the vicinity of the seed crystal 2.

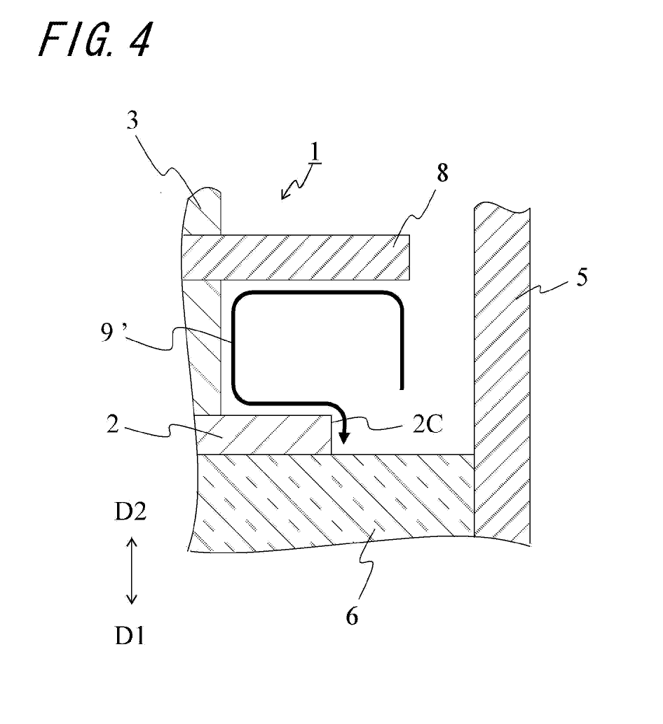

In addition, as illustrated in FIG. 4, since a part of the upper surface 2A of the seed crystal 2, specifically, a peripheral part, is exposed, the holder 1 of the embodiment has a space which is surrounded by the seed crystal 2, the holding member 3, and the suppressing member 8. Accordingly, vapor 9′ of the solution 6 flows along the lower surface of the suppressing member 8, the side surface 3B of the holding member 3, and the upper surface 2A of the seed crystal 2, and thereafter flows along the side surface 2B of the seed crystal 2. As a result, it is possible to maintain the temperature of a side surface 2C of the seed crystal 2, and to suppress the growth of miscellaneous crystals in the vicinity of the side surface 2C of the seed crystal 2.

Here, instead of suppressing the movement of the vapor 9, the suppressing member 8 may function as a reflecting plate which reflects radiant heat from the solution 6. In the holder 1 of the embodiment, the suppressing member 8 which is positioned above the seed crystal 2 also has a function of reflecting the radiant heat from the solution 6 to the upper surface 2A of the seed crystal 2. As a result, since the temperature of the upper surface 2A of the seed crystal 2 and the temperature of the solution 6 which is positioned in the vicinity of the seed crystal 2 are maintained, it is possible to make it difficult for miscellaneous crystals to be grown in the solution 6.

Furthermore, the outer circumference of the suppressing member 8 of the embodiment is set to be larger than that of the seed crystal 2. Accordingly, it is possible to make it easy to reflect the vapor 9 (radiant heat) from the solution 9 and to reach the side surface 2C of the seed crystal 2, to suppress the growth of miscellaneous crystals on the side surface of the seed crystal 2, and to make the crystal which is grown on the lower surface 2B large and long.

In the holder in the related art, since the suppressing member is not provided, it is likely for miscellaneous crystals to grow on the upper surface and the side surface of the seed crystal. Accordingly, since the growth speed of the miscellaneous crystals is much faster than that of the crystal which is grown on the lower surface of the seed crystal, the growth of the crystal is interrupted by the miscellaneous crystals. As a result, it is difficult to make the crystal large and long.

(Modification 1 of Holder)

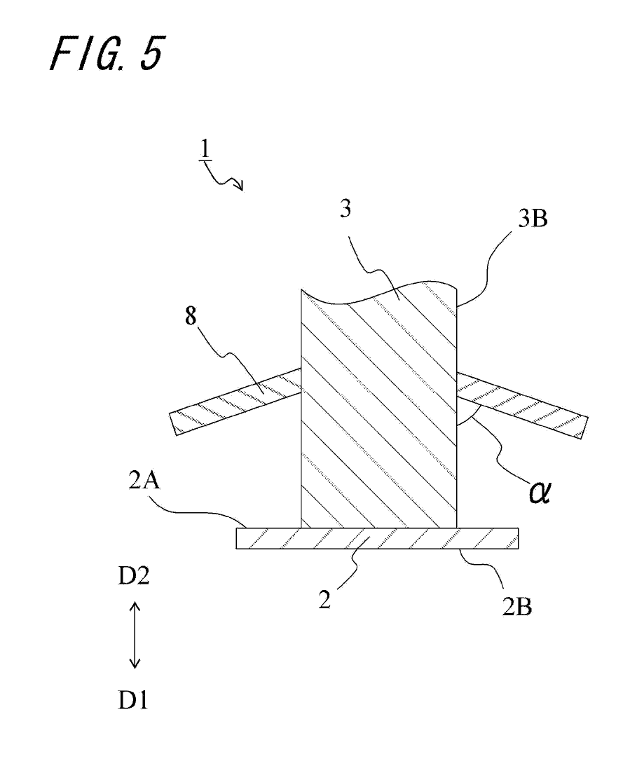

As illustrated in FIG. 5, the suppressing member 8 may be inclined in a downward direction (D1 direction) from the side surface 3B of the holding member 3. In particular, the suppressing member 8 is inclined with respect to the upper surface 2A of the seed crystal 2. An inclination angle α between the side surface 3B of the holding member 3 and the suppressing member 8 can be set to be smaller than 90°, for example. As the suppressing member 8 is inclined in the downward direction, it is possible to make it easy for the vapor 9 to be reflected to the upper surface 2A and the side surface 2C side of the seed crystal 2. As a result, it is possible to further suppress the growth of miscellaneous crystals in the vicinity of the upper surface 2A and the side surface 2C of the seed crystal 2, and to make the crystal which is grown on the lower surface 2B large or long.

(Modification 2 of Holder)

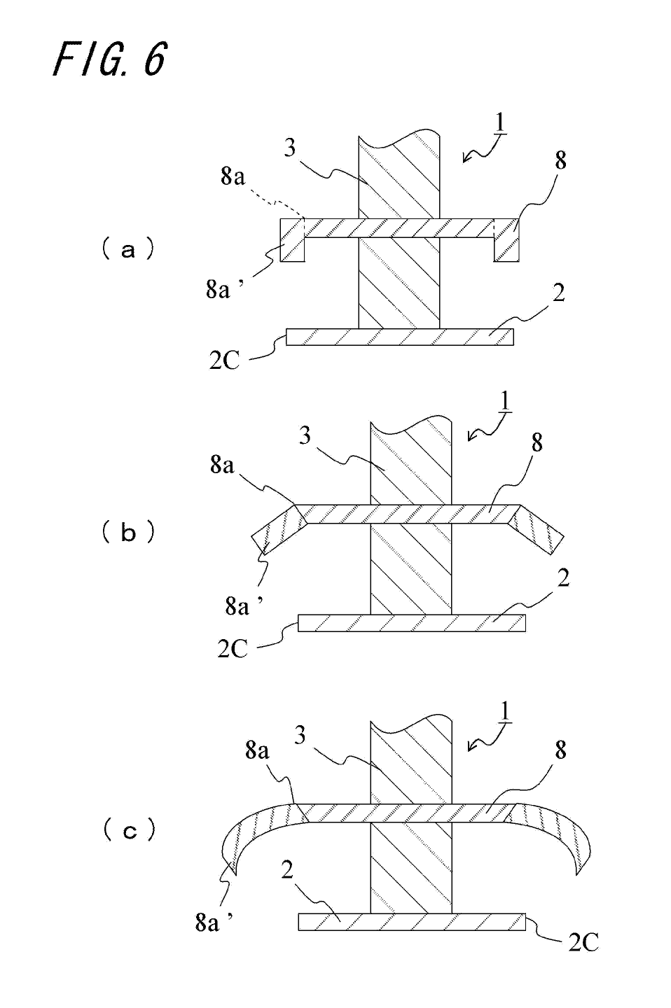

As illustrated in FIG. 6, the suppressing member 8 may have a bent portion 8a which is bent in the downward direction on the way to the outer circumference from the side surface 3B of the holding member 3. Here, in the description below, in the suppressing members 8, a portion of the suppressing member 8 which is positioned on the outer circumferential side further outward than bent portion 8a is referred to as a bent region 8a′.

The bent portion 8a may exist at any position of the suppressing member 8. In particular, the bent portion 8a represents a position of the suppressing member 8 at which the suppressing member 8 is bent in the downward direction. One or more bent portions 8a may be provided. For example, as illustrated in FIG. 6(a), when the bent portion 8a which is bent at a right angle with respect to the upper surface 2A of the seed crystal 2 is provided, it is possible to retain the vapor 9 in the space which is surrounded by the suppressing member 8, the holding member 3, and the seed crystal 2. Accordingly, it is possible to further suppress the growth of miscellaneous crystals in the vicinity of the seed crystal 2.

As illustrated in FIG. 6(b), the bent region 8a′ may be inclined with respect to the upper surface 2A of the seed crystal 2. In the bent region 8a′, an angle (inclination angle) formed between the suppressing member 8 and the bent region 8a′ is set to be greater than 90° and less than 180° with respect to the suppressing member 8 (a part other than the bent region 8a′). The inclination angle of the bent region 8a′ can be determined, for example, considering how the radiant heat from the solution 6 is reflected to the side surface 2C side of the seed crystal 2. When the bent region 8a′ which is inclined in this manner is provided, it is possible to make it easy for thermal radiation from the solution 6 to be reflected in a direction of the side surface 2C, and suppress the growth of miscellaneous crystals in the vicinity of the side surface 2C.

In addition, as illustrated in FIG. 6(c), the bent region 8a′ may be curved. A direction of the curve can be set such that the bent region 8a′ is curved outward with respect to the seed crystal 2, for example. In this manner, since the bent region 8a′ is curved, it is possible to more effectively reflect thermal radiation to the side surface 2C of the seed crystal 2. In other words, the direction of the curve can be set so as to reflect thermal radiation intensively to the side surface 2C of the seed crystal 2. In particular, a curved line when the bent region 8a′ is viewed in a cross-sectional view may be provided with a part which becomes a secondary curve of which a focus is in the vicinity of the side surface 2C. Accordingly, it is possible to further suppress the growth of miscellaneous crystals in the vicinity of the side surface 2C of the seed crystal 2.

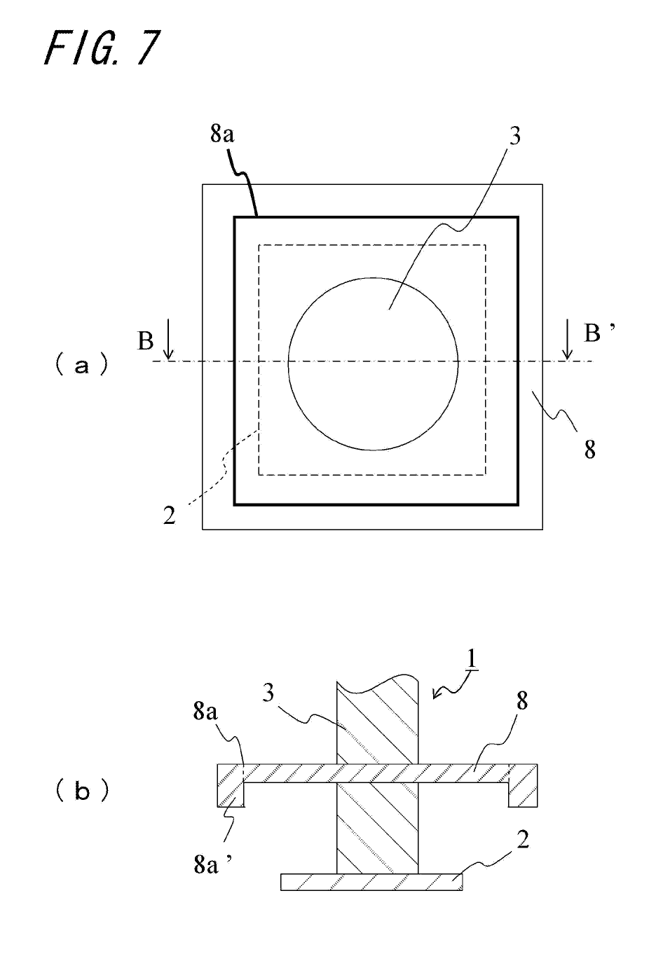

Furthermore, as illustrated in FIG. 7, the bent portion 8a may be disposed on the outside further outward than the outer circumference of the seed crystal 2. When the bent portion 8a is disposed on the outside further outward than the outer circumference of the seed crystal 2, the vapor 9 of the solution 6 can be easily taken into the space which is surrounded by the suppressing member 8, the holding member 3, and the seed crystal 2. With a result that the vapor 9 is easily taken into the space, it is possible to maintain the temperature of the upper surface 2A of the seed crystal 2, and to further suppress the growth of miscellaneous crystals.

(Modification 3 of Holder)

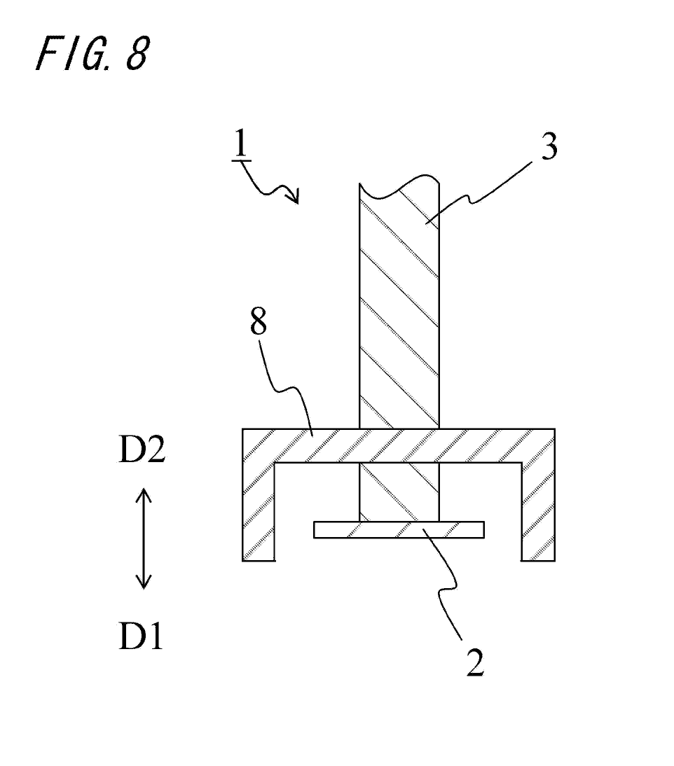

As illustrated in FIG. 8, the bent region 8a′ of the suppressing member 8 may be disposed such that an end portion thereof is immersed in the solution 6. In particular, in the holder 1, the end portion of the bent region 8a′ which is a part of the suppressing member 8 and is bent at 90° may be disposed to be positioned further downward than the lower surface 2B of the seed crystal 2 in a vertical direction.

When such holder 1 is used, the end portion of the suppressing member 8 is immersed in the solution 6 and is disposed so as to cover the seed crystal 2. In this case, in an initial stage of growing the crystal when growing the crystal is initiated on the lower surface 2B of the seed crystal 2, since a temperature in the vicinity of the seed crystal 2 can be maintained to be high, it is possible to suppress the growth of miscellaneous crystals in the vicinity of the seed crystal 2. When the structure is adopted during the entire process of growing the crystal, a length of a part, which is immersed in the solution 6, of the suppressing member 8 may be set to be longer than a thickness of the crystal which is grown on the lower surface 2B.

(Modification 4 of Holder)

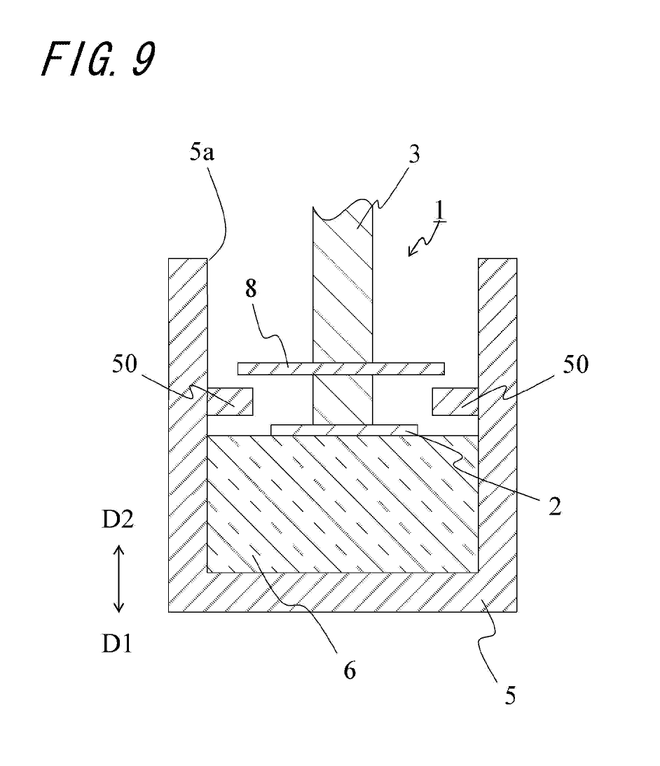

Furthermore, as illustrated in FIG. 9, a second suppressing member 50 may be provided in a crucible 5. The second suppressing member 50 may be provided to be integrated with the crucible 5, or may be attached to the crucible 5. For example, the same material as the suppressing member 8 can be selected as the material of the second suppressing member 50.

When the seed crystal 2 is in contact with the solution 6, the second suppressing member 50 is positioned higher than the seed crystal 2, and is positioned lower than the suppressing member 8. In this case, the second suppressing member 50 is made such that an opening is larger than the outer circumference of the seed crystal 2 and the opening is smaller than the outer circumference of the suppressing member 8.

Since the second suppressing member 50 is provided in the crucible 5 in this manner, it is possible to suppress the upward movement of the vapor of the solution 6. In addition, since the second suppressing member 50 is disposed in the crucible 5, it is possible to particularly suppress the upward movement of the vapor along an inner wall surface 5A of the crucible 5.

In the modification, a configuration in which the second suppressing member 50 is disposed between the seed crystal 2 and the suppressing member 8 is described, but the second suppressing member 50 may be disposed above the suppressing member 5. In this case, the opening of the second suppressing member 50 may be provided to be larger than the outer circumference of the suppressing member 5 so that the holder 1 is taken into and out of the crucible 5.

<Second Embodiment of Holder>

As illustrated in FIG. 9, compared to the holding member 3 of the first embodiment, a holder 100 according to this embodiment is different in that a holding member 30 is formed of a first holding portion 30a and a second holding portion 30b.

The same material as the above-described holding member 3 can be selected as the material of the holding member 30 (first holding portion 30a and second holding portion 30b). An area of a lower surface of the first holding portion 30a can be smaller than that of the upper surface 2A of the seed crystal 2. The second holding portion 30b can use the configuration of the suppressing member 8 of the holder 1 of the first embodiment.

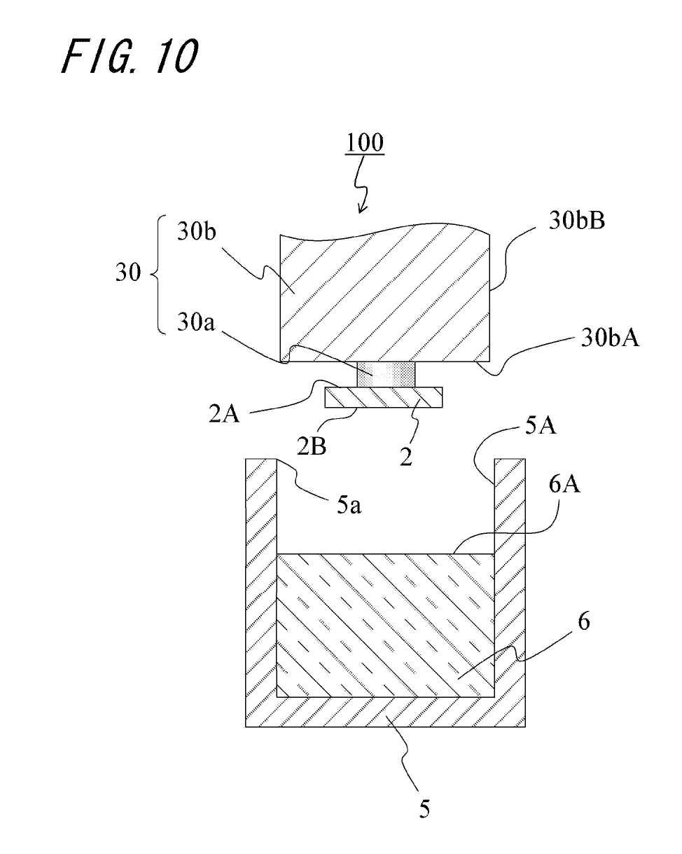

In particular, as illustrated in FIG. 10, in the second holding portion 30b, an outer circumference is set to be smaller than an inner circumference of the opening 5a of the crucible 5, and the outer circumference is set to be larger than the outer circumference of the seed crystal 2. In other words, when viewed in a longitudinal sectional view, a width Re1 of the second holding portion 30b is set to be less than a width (interval between the inner wall surfaces) Re2 in the crucible 5, and is set to be greater than a width Re3 of the seed crystal 2. In other words, the relationship between the Re1, the Re2, and the Re3 is expressed as “Re3<Re1≦Re2”. In addition, Re1=Re2 represents a case where the widths are set to be almost the same.

The width Re1 of the second holding portion 30b may be determined in accordance with an interval Re4 between an outer side surface 30bB of the second holding portion 30b and the inner wall surface 5A and an amount of vapor generated from the solution 6. The interval Re4 can be set to 1.5 mm or more and 2 cm or less, for example. Accordingly, the width of the second holding portion 30b can be set to 4 cm or more and 30 cm or less, for example.

The length of the second holding portion 30b in a longitudinal direction may be set such that when the second holding portion 30b is inserted into the crucible 5, the length is longer than a distance from the opening 5a to a liquid surface 6A of the solution 6. In particular, the length of the second holding portion 30b can be set to 5 cm or more and 30 cm or less, for example. In addition, the first holding portion 30a and the second holding portion 30b may be integrally formed, or for example, may be bonded by carbon adhesive.

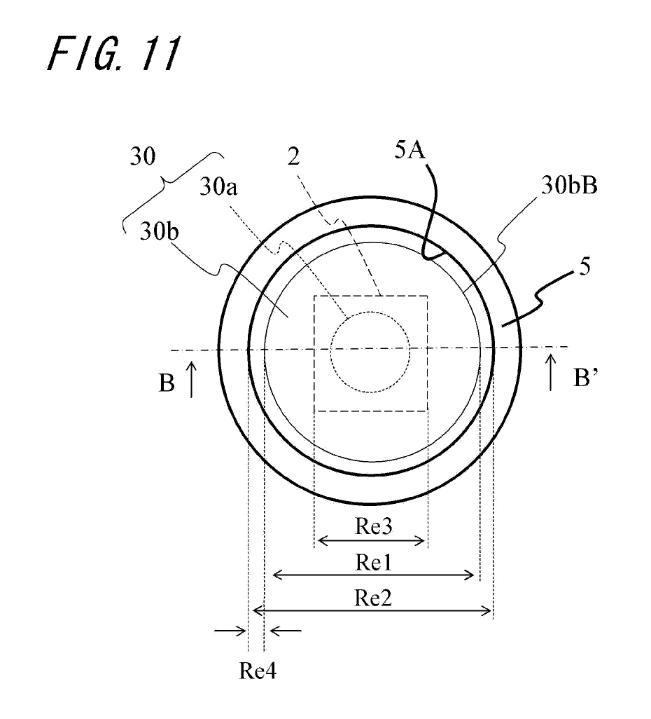

In the holder of the embodiment, the seed crystal 2 is attached to the second holding portion 30b via the first holding portion 30a. Since the holder 100 has the second holding portion 30b which has the outer circumference smaller than the inner circumference of the opening 5a and the outer circumference larger than that of the seed crystal 2, a part of a lower surface 30bA of the second holding portion 30b is exposed from the seed crystal 3. Accordingly, when the crystal is grown on the lower surface 2B of the seed crystal 2, as illustrated in FIG. 11, a radiant heat Th from the solution 6 can be reflected in a direction of the liquid surface 6A of the solution 6 at an exposed part of the lower surface 30bA.

As a result, since the temperature of the liquid surface 6A in the vicinity of the seed crystal 2 is unlikely to be lowered, it is possible to maintain the temperature of the vicinity of the liquid surface 6A of the solution 6, and to suppress the growth of miscellaneous crystals in the vicinity of the seed crystal 2.

In addition, since the size of the second holding portion 30b is set as described above, it is possible to make the interval Re4 between the inner wall surface 5A of the crucible 5 and the second holding portion 30b small. By making the interval Re4 between an outer side surface 30bB of the second holding portion 30b and the inner wall surface 5A of the crucible 5 small, as illustrated in FIG. 11, it is possible to make it difficult for a vapor Mo from the solution 6 to escape.

Reasons thereof may be given such that, when the interval Re4 is small, for example, the movement of the vapor Mo is interrupted by the second holding portion 30b and the total amount of the vapor Mo which escapes to the outside of the crucible 5 can be small, or the vapor Mo along the exposed part of the lower surface 30bA is likely to flow to the solution 6 side along the inner wall surface 5A. Accordingly, since the vapor Mo from the solution 6 can be retained in the space between the liquid surface 6A and the lower surface 30bA, it is possible to make the volume of the vapor Mo from the solution 6 small, and to make a heat of vaporization generated in the vicinity of the liquid surface 6A small. As a result, it is possible to maintain the temperature of the vicinity of the liquid surface 6A, and to suppress the growth of miscellaneous crystals in the vicinity of the seed crystal 2.

Furthermore, since an amount of evaporation from the solution 6 can be made small in this manner, it is possible to stably maintain the composition of the solution 6. As a result, even when the growth of the crystal is performed for a long time, it is possible to suppress an irregularity or a bunching of the composition in the grown crystal.

(Modification 1 of Holder)

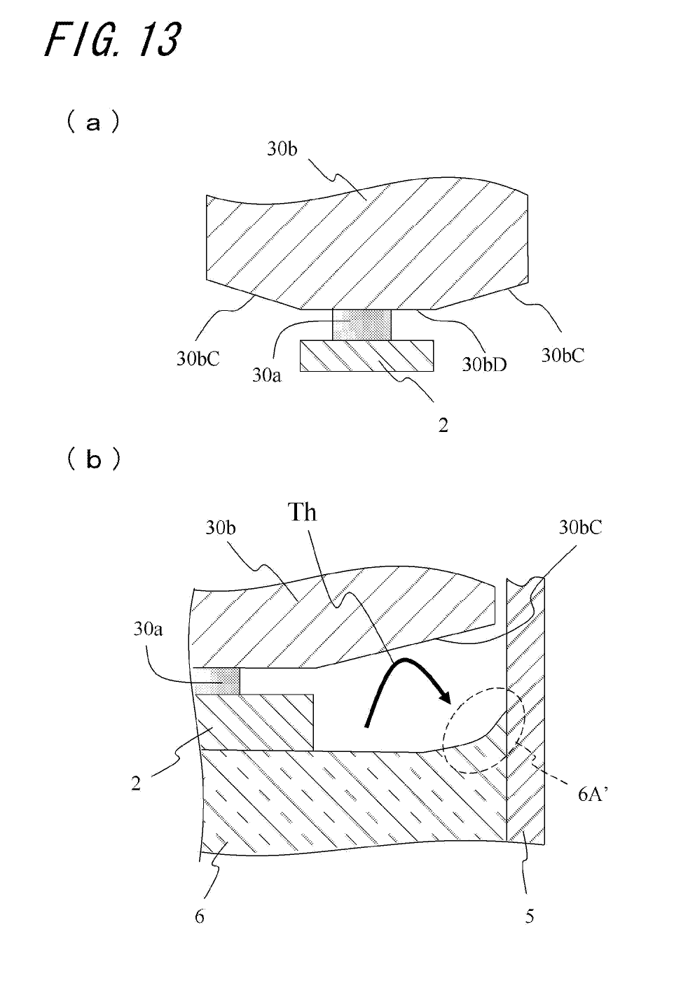

As illustrated in FIG. 13(a), in the second holding portion 30b, an exposed part 30bC of the lower surface 30bA which is exposed from the upper surface of the seed crystal 2 may be inclined upward from a holding part 30bD of the lower surface 30bA which indirectly holds the seed crystal 2. The inclination of the exposed part 30bC is set to 1° or more and 10° or less, for example, with respect to the holding part 30bD.

By inclining the exposed part 30bC upward in this manner, as illustrated in FIG. 13(b), it is possible to make it easy for the radiant heat Th from the solution 6 to reach a meniscus 6A′ in which a part of the solution 6 extends along the inner wall surface 5A. As a result, it is possible to maintain the temperature of the vicinity of the meniscus 6A′, and it is possible to suppress the growth of miscellaneous crystals in the vicinity of the meniscus 6A′ and to prevent to some extent the meniscus 6A′ itself from becoming miscellaneous crystals.

In addition, when the exposed part 30bC is inclined upward in this manner, even when the temperature of the second holding portion 30b is low as compared to the temperature of air inside the crucible 5, it is possible to make the exposed part 30bC separated from the liquid surface 6A, and to make it difficult to lower the temperature in the vicinity of the liquid surface 6A of the solution 6.

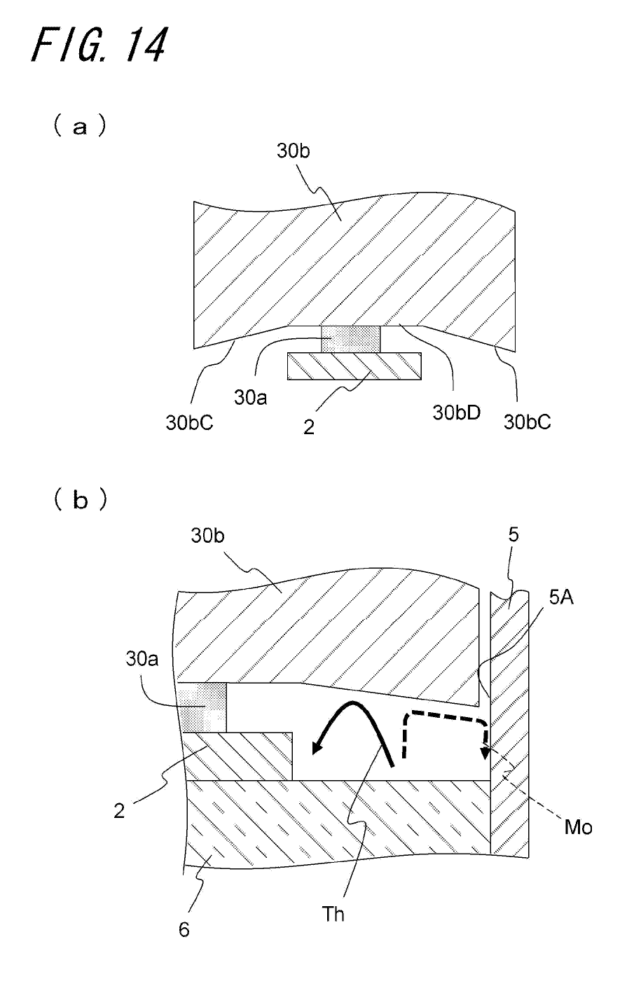

Meanwhile, as illustrated in FIG. 14(a), the exposed part 30bC may be inclined downward from the holding part 30bD. In this case, it is possible to make it easy for the radiant heat Th to be reflected in a direction of the seed crystal 2, and to make it difficult for the temperature of the solution 6 in the vicinity of the seed crystal 2 to be lowered. In addition, in this case, since an angle formed between the exposed part 30bC and the inner wall surface 5A can be made small, as illustrated in FIG. 14(b), it is possible to make it easy for the vapor Mo along the lower surface 3A to flow along the inner wall surface 5A, and to make it difficult for the vapor to escape to the outside of the crucible 5.

(Modification 2 of Holder)

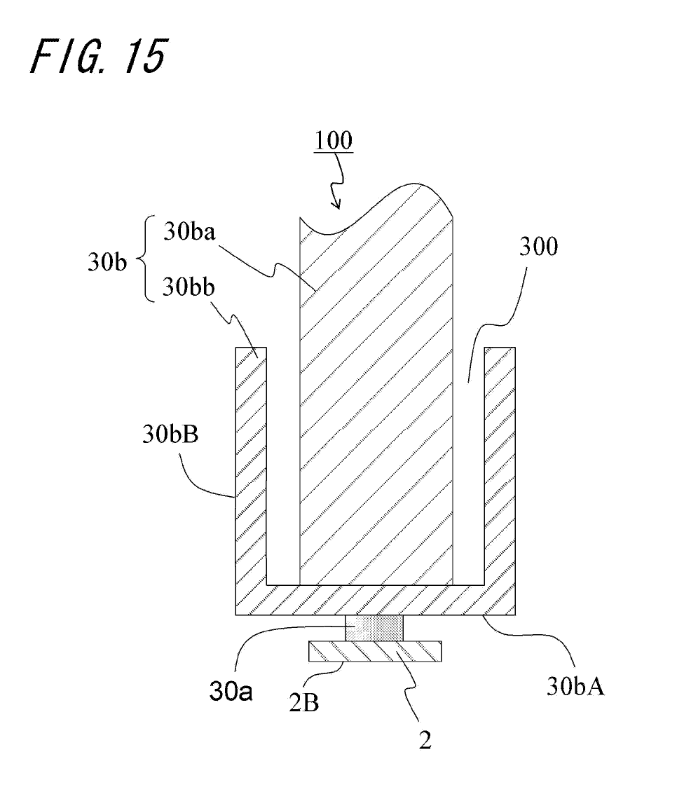

As illustrated in FIG. 15, the second holding portion 30b may be provided with a cavity 300 which is positioned above the exposed part 30bC of the lower surface 30bA which is exposed from the upper surface of the seed crystal 2. As illustrated in FIG. 15, the cavity 300 can be formed of a shaft member 30ba and a shield member 30bb. In the embodiment, it is possible to use a member in a pillar shape as the shaft member 30ba, and to use a member in a bowl shape like the crucible 5, for example, as the shield member 30bb.

As described above, since it is required for the temperature of the seed crystal 2 to be low with respect to the temperature of the solution 6 in a solution growth method, it is required for the heat of the seed crystal 2 to be transferred to the holding member 30. In other words, by making the temperature of the holding member 30 low with respect to the temperature of the seed crystal 2, the holding member 30 can more effectively lower the temperature of the seed crystal 2, and can contribute to the quality or the like of the crystal which is grown on the lower surface 2B.

Accordingly, when the solution 6 or the like is heated by an induction heating method, by forming the cavity 300 in the second holding portion 30b as in the modification, it is possible to attenuate an RF energy of a coil 13 by the cavity 300. Since the RF energy of the coil 13 is attenuated by the cavity 300 in this manner, it is possible to suppress the temperature rise of the shaft member 30ba. As a result, since the temperature rise of the seed crystal 2 can be suppressed, it is possible to maintain the growing speed of the crystal which is grown on the lower surface 2B.

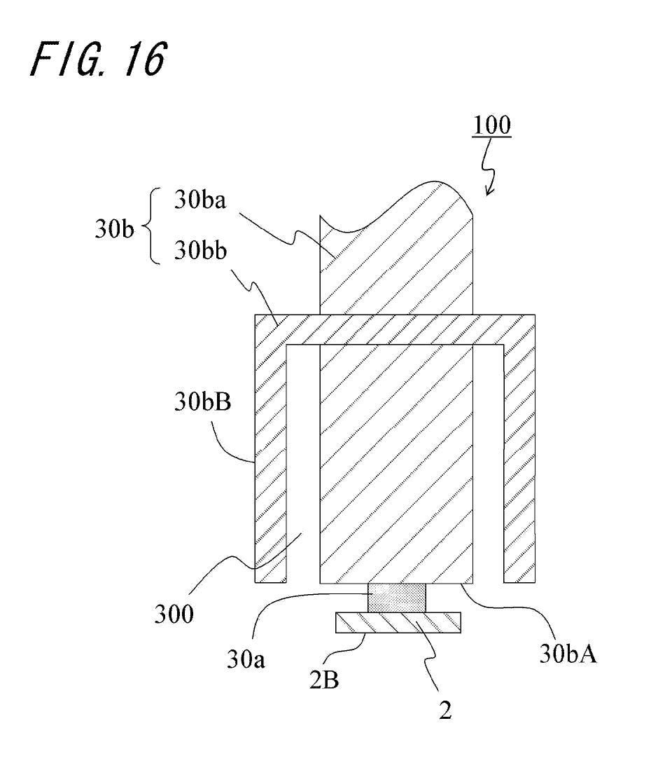

In addition, as illustrated in FIG. 16, the opening of the cavity 300 may be set to be provided below. In this case, since the cavity 300 exists in the vicinity of the lower surface 30bA of the second holding portion 30b which holds the seed crystal 2, it is possible to suppress the temperature rise of the shaft member 30ba in the vicinity of the seed crystal 2. In addition, in a case of an example illustrated in FIG. 16, the lower surface 30bA of the second holding portion 30b represents the entire region which is surrounded by the outer circumference of the shield member 30ba, and for example, the seed crystal 2 may be held on the lower surface of the shaft member 30ba and the shield member 30ba to be across the cavity 300.

(Modification 3 of Holder)

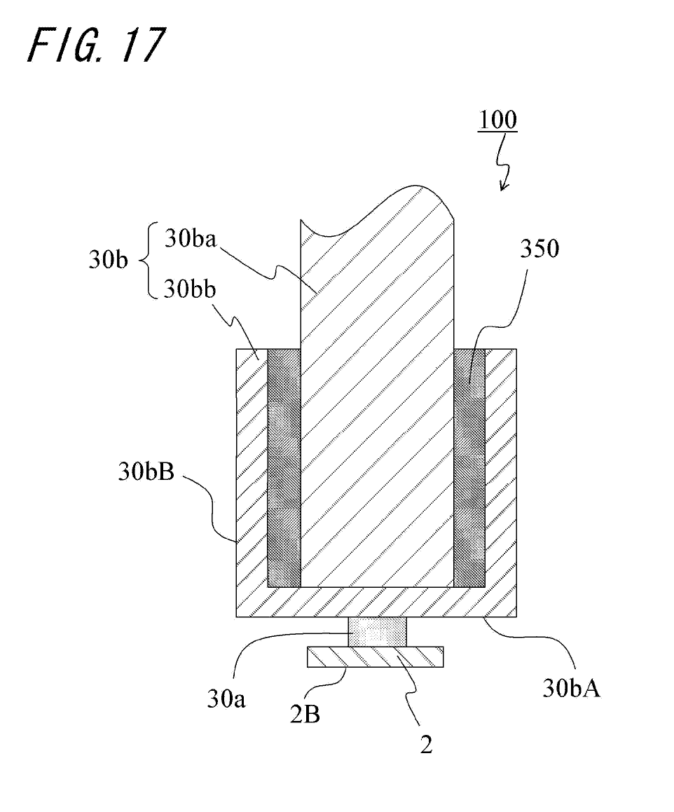

Furthermore, as illustrated in FIG. 17, the cavity 300 may be filled with a material which has a lower thermal conductivity than that of the second holding portion 30b, more specifically, a heat insulating material 350. It is not required for the heat insulating material 350 to fill the entire cavity 300, and there may be a partial space inside the cavity 300. Furthermore, preferably, a material which has a lower heat conductivity than that of air may be used as the heat insulating material 350. When the cavity 300 is filled with the heat insulating material 350, the RF energy of the coil 13 is further attenuated by the heat insulating material 350 in the cavity 300, and it is possible to suppress the temperature rise of the shaft member 30ba.

<Crystal Growing Method>

Next, a crystal growing method of the present invention will be described. The crystal growing method of the present invention includes a first preparation step, a second preparation step, and a growing step.

(First Preparation Step and Second Preparation Step)

In the first preparation step, the crucible 5 for growing the crystal, which has the opening 5a at the upper end thereof and stores the solution 6 of silicon having carbon, is prepared. In addition, the above-described holder 1 is prepared.

(Growing Step)

Next, in the crystal growing apparatus 4 described below, while placing the holder 1 into the crucible 5 through the opening 5a and positioning the suppressing member 8 together with the seed crystal 2 in the crucible 5, the lower surface 2B of the seed crystal 2 is in contact with the solution 6, and the holder 1 is pulled up. Accordingly, it is possible to grow the crystal of the silicon carbide from the solution 6 on the lower surface 2B of the seed crystal 2.

According to the crystal growing method of the embodiment, by using the holder 1 having the suppressing member 8 and by growing the crystal on the lower surface 2B of the seed crystal 2, it is possible to suppress the growth of miscellaneous crystals in the vicinity of the seed crystal 2. Accordingly, it is possible to make the crystal which is grown on the lower surface 2B large and long. In other words, since the crystal can be made large and long as compared to that in the related art, it is possible to improve a productivity of the crystal which is grown.

<Crystal Growing Apparatus>

Next, the crystal growing apparatus 4 according to the embodiment of the present invention will be described with reference to FIG. 17. The crucible 5 is disposed inside a crucible container 10. The crucible container 10 has a function of holding the crucible 5. A heat reserving material 11 is disposed between the crucible container 10 and the crucible 5. The heat reserving material 11 surrounds the crucible 5. The heat reserving material 11 suppresses the radiation of heat from the crucible 5, and contributes to stably keeping the temperature of the crucible 5.

The crucible 5 functions as a container which fuses a raw material of a single crystal of the silicon carbide to be grown. In the embodiment, the crucible 5 stores the solution 6 which dissolves carbon by using the fused silicon as a solvent. In the embodiment, a solution growing method is employed, and the growth of the crystal is performed by making a state which is close to a thermal equilibrium in the crucible 5.

In the crucible 5, the heat is added by a heating mechanism 12. The heating mechanism 12 of the embodiment employs the induction heating method which heats the crucible 5 by the electromagnetic induction, and has a configuration in which the coil 13 and an AC power supply 14 are included. The crucible 5 is made of a material which has silicon (graphite) as a main component, for example.

The solution 6 is disposed in the crucible 5. The solution 6 is a solution which dissolves carbon which is an element that constitutes the crystal of the silicon carbide which is grown on the lower surface 2B of the seed crystal 2 into the solution of silicon which is an element that constitutes the crystal of the silicon carbide which is grown similarly. A solubility of an element which becomes a solute is great as the temperature of the element which becomes a solvent increases. Accordingly, when the temperature of the lower surface 2B of the seed crystal 2 is slightly lower than the temperature of the solution 6, the temperature of the solution 6 which dissolves many of the solutes into the solvent at a high temperature becomes low in the vicinity of the seed crystal 2, and the solutes on the boundary which are thermally equivalent are deposited. By using the deposition according to the thermal equilibrium, it is possible to grow the crystal of the silicon carbide on the lower surface 2B of the seed crystal 2.

The coil 13 is formed of a conductor and is wound to surround the crucible 5. The AC power supply 14 is provided for causing an AC current to flow in the coil 13, and it is possible to shorten the heating time to the set a temperature in the crucible 5 by causing a much greater AC current to flow.

In the embodiment, the crucible 5 is heated by the induction heating method. Alternatively, the heating may be performed by causing an induced current to flow in the solution 6 itself by an electromagnetic field. When the solution 6 itself is heated in this manner, the crucible 5 itself may not be heated.

The seed crystal 2 is supplied to the solution 6 of the crucible 5 by a transport mechanism 15. The transport mechanism 15 has a function of taking out the crystal which is grown on the lower surface 2B of the seed crystal 2. The transport mechanism 15 includes the holding member 3 and a power source 16. Taking in and out the seed crystal 2 and the crystal which is grown on the lower surface 2B of the seed crystal 2 is performed via the holding member 3. The seed crystal 2 is attached to the lower surface 3A of the holding member 3, and the movement of the holding member 3 in a vertical direction (D1 and D2 directions) by the power source 16 is controlled.

In the crystal growing apparatus 4, the AC power supply 14 of the heating mechanism 12 and the power source 16 of the transport mechanism 15 are connected to a control portion 17 and are controlled. In other words, by the control portion 17, the crystal growing apparatus 4 is controlled by linking the heating control and the temperature control of the solution 6 with the taking in and out of the seed crystal 2. The control portion 17 includes a central processing apparatus and a storage unit, such as a memory, and is, for example, a computer which is known.

The holding member 3 of the above-described holder 1 is attached to the transport mechanism 15 of the crystal growing apparatus 4 of the embodiment. By making the lower surface 2B of the seed crystal 2 which is fixed to the lower surface 3A of the holding member 3 in contact with the solution 6, it is possible to grow the crystal on the lower surface 2B. Note that, in the crystal growing apparatus 4 of the embodiment, the crystal is grown by attaching the above-described holder 1 to the transport mechanism 15.

Since the crystal growing apparatus 1 having the above-described holder 1 can suppress the growth of miscellaneous crystals in the vicinity of the seed crystal 2, it is possible to make the crystal to be grown large and long.

The present invention is not limited to the above-described embodiments and the modifications, and may be employed in various aspects. For example, in the above-described embodiments, a case where the suppressing member is fixed to the holder is described, but the suppressing member may be fixed only to the crucible (configuration in which only a second holding member is provided). In this case, the suppressing member can be set to have an opening which is larger than the outer circumference of the seed crystal.

In addition, as illustrated in FIG. 18, the suppressing member may be attached only to the crucible container 10. In this case, in plan view, the opening of the suppressing member may be disposed to be further inward than the opening of the crucible 5. By the suppressing member, it is possible to suppress the upward movement of the vapor of the solution 6.

1. A holder which is used in a solution growth method of growing a crystal on a lower surface of a seed crystal by contacting the lower surface of the seed crystal with a solution of silicon including carbon in a crucible having an opening on an upper end thereof, the holder comprising:
a holding member which holds the seed crystal on a lower surface of the holding member;
the seed crystal which is held on the lower surface of the holding member, has an upper surface larger than the lower surface of the holding member, and is made of silicon carbide; and
a suppressing member which is fixed to a side surface of the holding member, continues from the side surface to outside further outward than an outer circumference of the seed crystal in plan view, and suppresses upward movement of vapor from the solution.

2. The holder according to claim 1,
wherein the suppressing member is inclined in a downward direction from the side surface of the holding member.

3. The holder according to claim 1 or 2,
wherein the holding member and the suppressing member are made of carbon, and the suppressing member is fixed to the holding member by an adhesive including carbon.

4. The holder according to claim 1,
wherein the suppressing member comprises a bent portion which is bent in a downward direction on the way to the outer circumference from the side surface of the holding member.

5. The holder according to claim 4,
wherein the bent portion is disposed outside of the outer circumference of the seed crystal.

6. The holder according to claim 1,
wherein the holding member comprises a first holding portion which holds the seed crystal on a lower surface thereof that is smaller than the upper surface of the seed crystal, and a second holding portion which is fixed to an upper surface of the first holding portion and is larger than the outer circumference of the seed crystal in plan view.

7. The holder according to claim 6,
wherein a part of a lower surface of the second holding portion is exposed from the upper surface of the first holding portion, and the exposed part is inclined upward from a holding part of the lower surface of the second holding portion, the holding part holding the upper surface of the first holding portion.

8. The holder according to claim 6,
wherein a part of a lower surface of the second holding portion is exposed from the upper surface of the first holding portion, and a cavity is included inside the second holding portion and positioned above the exposed part.

9. The holder according to claim 8,
wherein the cavity is filled with a material which has a heat conductivity lower than that of the second holding portion.

10. A crystal growing method comprising:
a first preparation step of preparing a crucible for growing a crystal, which has an opening at an upper end thereof and in which a solution of silicon including carbon is stored;
a second preparation step of preparing the holder according to claim 1; and
a growing step of growing the crystal of silicon carbide from the solution on a lower surface of the seed crystal, by placing the holder in the crucible through the opening, positioning the suppressing member in the crucible together with the seed crystal, contacting the lower surface of the seed crystal with the solution, and pulling up the holding member.

11. A crystal growing apparatus comprising:
a crucible for growing a crystal, which has an opening at an upper end thereof and in which a solution of silicon having carbon is stored;
a holding member which is capable of being taken into and out of the crucible through the opening, and holds, on a lower surface of the holding member, a seed crystal having an upper surface larger than the lower surface of the holding member; and
a suppressing member which is fixed to a side surface of the holding member, continues from the side surface to outside further outward than an outer circumference of the seed crystal in plan view, and suppresses upward movement of vapor from the solution.

12. The holder according to claim 2,
wherein the holding member and the suppressing member are made of carbon, and the suppressing member is fixed to the holding member by an adhesive including carbon.

13. The holder according to claim 2,
wherein the suppressing member comprises a bent portion which is bent in a downward direction on the way to the outer circumference from the side surface of the holding member.

14. The holder according to claim 13,
wherein the bent portion is disposed outside of the outer circumference of the seed crystal.

15. The holder according to claim 3,
wherein the suppressing member comprises a bent portion which is bent in a downward direction on the way to the outer circumference from the side surface of the holding member.

16. The holder according to claim 15,
wherein the bent portion is disposed outside of the outer circumference of the seed crystal.

17. The holder according to claim 7,
wherein a part of a lower surface of the second holding portion is exposed from the upper surface of the first holding portion, and a cavity is included inside the second holding portion and positioned above the exposed part.

18. The holder according to claim 17,
wherein the cavity is filled with a material which has a heat conductivity lower than that of the second holding portion.
